(19) United States
(12) Patent Application Publication
(10) Pub. No.: US 2010/0027277 A1
(43) Pub. Date: Feb. 4, 2010

(54) LIGHT EMITTING DIODE PACKAGE

(75) Inventor: Cheng-Lien CHIANG, Taipei (TW)

Correspondence Address: LOWE HAUPTMAN HAM & BERNER, LLP, 1700 DIAGONAL ROAD, SUITE 300, ALEXANDRIA, VA, 22314, US

(73) Assignee: NICHEPAC TECHNOLOGY INC., Taipei County (TW)

(21) Appl. No.: 12/578,812

(22) Filed: Oct. 14, 2009

Related U.S. Application Data
(63) Continuation-in-part of application No. 11/749,150, filed on May 15, 2007, now Pat. No. 7,622,795.

(51) Int. Cl. F21V 21/00; H01L 33/00

(52) U.S. Cl. 362/382; 257/88; 257/E33.058

(57) ABSTRACT

A substrate structure for light emitting diodes (LED) chips operation includes a heat spreader, chip holders arranged in the center of the heat spreader, transfer pads located near the chip holders for wire bonding interconnection between the LED chips, and a circuit layer having a gap dividing the circuit layer diagonally. The circuit layer includes a first insulation layer on top of the heat spreader, a metal trace layer on top of the first insulation layer, and a second insulation layer on top of the metal trace layer, wherein portions of the second insulation layer are removed at the opposite corners along the gap, and around the opening, and a conductive plating is plated on the second insulation layer around the opening. Furthermore, a spotlight cap is provided to focus the light emitted from the LED. A LED package includes the substrate structure and the spotlight cap is also provided.

This application is a continuation-in-part application of U.S. application Ser. No. 11/749,150 filed on May 15, 2007, the disclosure of which is incorporated by reference herein in its entirety.

### BACKGROUND

1. Field of Invention

The present invention relates to a substrate structure. More particularly, the present invention relates to a substrate structure for light emitting diode packages used in electronic devices.

2. Description of Related Art

In order for the light emitting diodes (LED) to be used in electronic devices, it is essential that the LED substrate have a high heat resistant property, wide light radiation angle, and ease of assembly. In prior attempts to achieve this goal, one has attempted in using a copper substrate divided into two isolated conductors by an insulation layer and mounting on the substrate layer is another insulation layer with circuit patterns providing an electrical path for the LED chip operation. Further more, the prior art design does not support multiple chips on a single substrate. Also, to assembly multiple substrates together while driving the LEDs with a single pair of power cables, the placement of power connectors are crucial to provide the shortest connection distance between the substrates.

Therefore, a new design of the LED substrate structure is needed for multiple chip placements on a single substrate while providing a high heat resistant property along with flexible assembly of multiple LED substrates.

### SUMMARY

The present invention is directed to a circuit substrate, that is satisfies this need of a new substrate structure for LED chips operation. The substrate structure includes a heat spreader, chip holders, transfer pads, and a circuit layer. The chip holders are arranged in the center of the heat spreader. The transfer pads are located near the chip holders for wire bonding interconnection between the LED chips. The circuit layer having a gap dividing the circuit layer diagonally includes a first insulation layer on top of the heat spreader, a metal trace layer on top of the first insulation layer, and a second insulation layer on top of the metal trace layer. Portions of the second insulation layer are removed at the opposite corners along the gap, and around the opening, and a conductive plating is plated on the second insulation layer around the opening. The head spreader is a single sheet of metal having a rectangular shape. The gap in the circuit layer isolates the metal traces layers from the heat spreader and from each other. Since the metal trace layer is exposed at the opposite corners of the circuit layer, the multiple substrates may be joined by placing the substrates adjacent to each other and connecting the adjacent respective exposed metal trace layers together via conducting strips. In addition, a conductive adhesive is applied on the chip pad to connect and also elevate the LED chips above the circuit layer surface, thus preventing the thickness of the circuit layer to block any emitted light.

Furthermore, a spotlight cap is provided to focus the light emitted from the LED. The spotlight cap is fastened onto the substrate structure and has through holes for gel injection from the backside of the heat spreader. Combining the substrate structure with the spotlight cap, a LED package is provided having multiple LED chips such as in a 2×2 or 3×3 arrangement to be placed thereon. The LED packages may be connected into LED panels for use such as head and taillight for automobiles, or as searchlights. Also, the LED packages may be assembled into a general-purpose light bulb. The ease of assembly allows for many variations in the application of LED packages.

It is to be understood that both the foregoing general description and the following detailed description are by examples, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIG. 1 is a general view of a substrate structure for LED chips operation according to a first embodiment of the present invention; and

FIG. 1a is a side view of the substrate structure according to the first embodiment of the present invention;

FIG. 2 is a general view of the substrate structure for LED chips operation with wire bonding chips thereon according to the first embodiment of the present invention;

FIG. 3 is a top view of the substrate structure for LED chips operation with wire bonding chips thereon according to the first embodiment of the present invention.

FIG. 4A is a top and bottom view the spotlight cup according to a second embodiment of the present invention.

FIG. 4B is a top and bottom view of an alternately spotlight cup according to a third embodiment of the present invention.

FIG. 5A is an exploded view of a LED circuit package according to a fourth embodiment of the present invention.

FIG. 5B is a general view of the LED circuit package according to the fourth embodiment of the present invention.

FIG. 6 is a 3-dimensional (3D) assembly of the LED circuit packages.

FIG. 7A is an exploded view of the general purpose light bulb.

FIG. 7B is an assembled view of the general purpose light bulb.

FIG. 8 is a three dimensional view for the LED package according to the present invention.

FIG. 9 is a section view along section line AA′ of FIG. 8.

FIG. 10 is a step cup used in this invention.

FIG. 11 is a section view along line BB′ of FIG. 10.

FIG. 12 is an assembly view of the step cup mounted onto the substrate stack.

FIG. 13 is a substrate with 6*2 matrix pattern of the present invention.

FIG. 14 is a parallel connection for the units on the substrate stack of FIG. 13.

FIG. 15 is a serial-parallel connection for the units on the substrate stack of FIG. 13.

FIG. 16 is an alternative pattern for the units on the substrate stack.

FIG. 17˜20 is a process for mounting the LED chip onto the substrate stack.

FIG. 21 is an assembly view for a step cup mounted on a substrate stack.

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

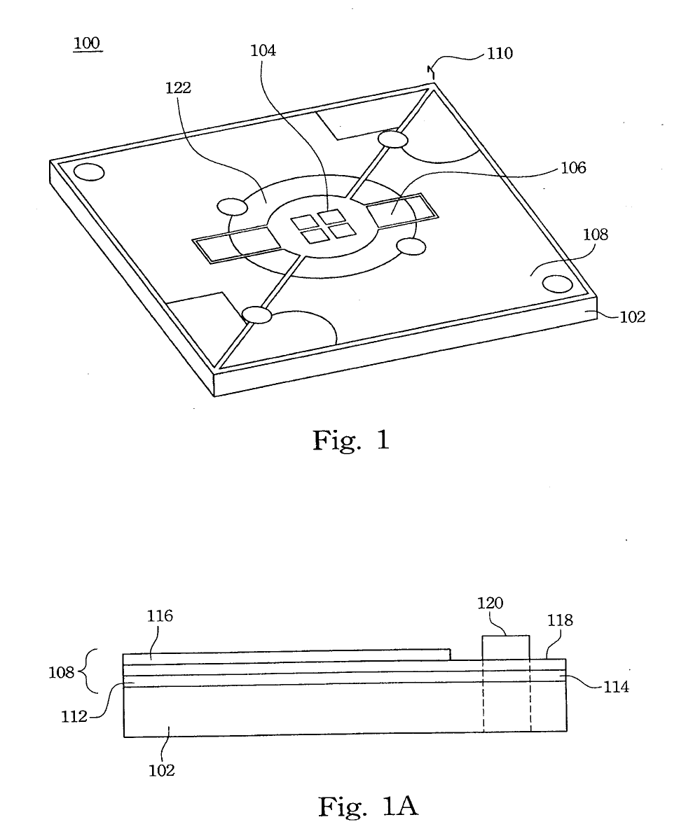

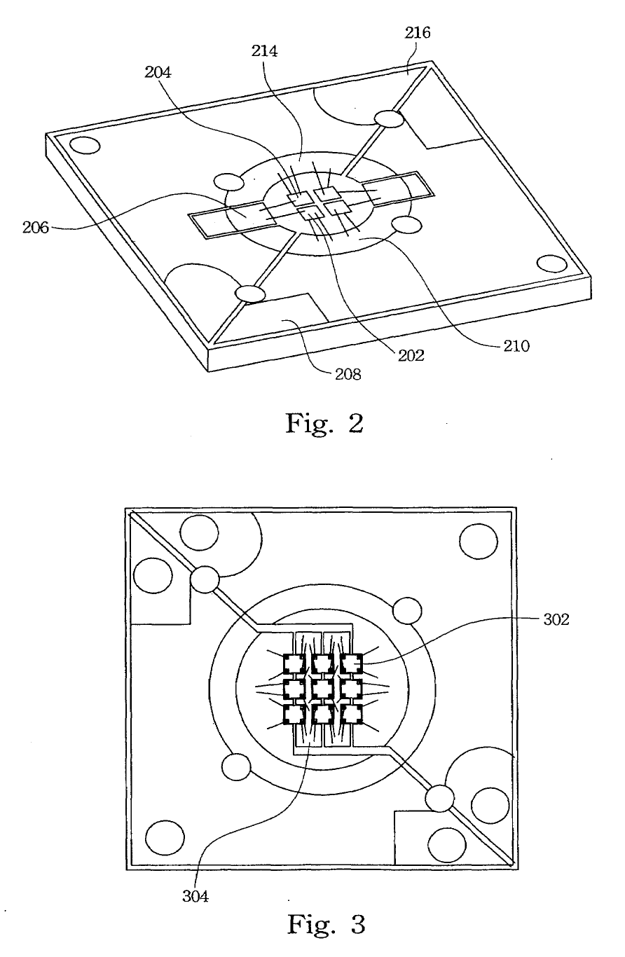

Please refer to FIG. 1, a general view of a substrate structure for LED chips operation according to a first embodiment of the present invention. The substrate structure 100 includes a heat spreader 102, chip holders 104, transfer pads 106, and a circuit layer 108. The heat spreader 102 may be made of a good heat conductor such as copper. The chip holders 104 are arranged in the center of the substrate in array form such as a 2×2 array, a 3×3 array, a 4×4 array, etc. In this embodiment, it is a 2×2 array of chip holders 104. The chip holders 104 are for fixing the LED chips in place using a conductive adhesive, which has good thermal conductivity, such as a solder paste. In the embodiment, the thickness of the solder paste also allows the LED chips to be above the surface of the circuit layer, preventing the emitted light to be block by the opening side walls of the circuit layer 108. The chip holders 104 also may be made of a gold material. Next, the transfer pads 106 are for bond wire connection of the LED chips, and will be addressed more specifically later in the description. The transfer pads 106 are plated for bond wire engagement and the plating is isolated from the heat spreader 102 and the circuit layer 108. The circuit layer 108 mounted on the heat spreader 102 and is divided diagonally forming a gap 110 and an opening surrounding the chip holders 104. The forming of the gap 110 is to separate the circuit layers to form two independent voltage nodes in the substrate structure.

In FIG. 1a, a partial side view of the substrate structure according to the first embodiment of the present invention, the circuit layer 108 includes a first insulation layer 112, a metal trace layer 114, and a second insulation layer 116. The first insulation layer 112 is directly on top of the heat spreader 102. The metal trace layer 114 is on top of the first insulation layer 112 and is isolated form the heat spreader 102. The metal trace layer 114 may have circuit patterns thereon. The second insulation layer 116 is mounted on top of the metal trace layer 114. The second insulation layer 116 is partially removed at the opposite corners along the dividing gap 110 of the circuit layer, thus exposing the metal trace layer 114 to allow contact access to the metal trace layer 114 at the corners of the circuit layer 108. Furthermore, the second insulation layer 116 is removed around the opening surrounding the chip pads 104, and the exposed metal trace layer 114 around the opening is plated by a conductive plating 122 such as gold. The conductive plating 122 is for the LED chips to be wire bonded thereon and be driven by the power supplied at the contact surface of the corners 118.

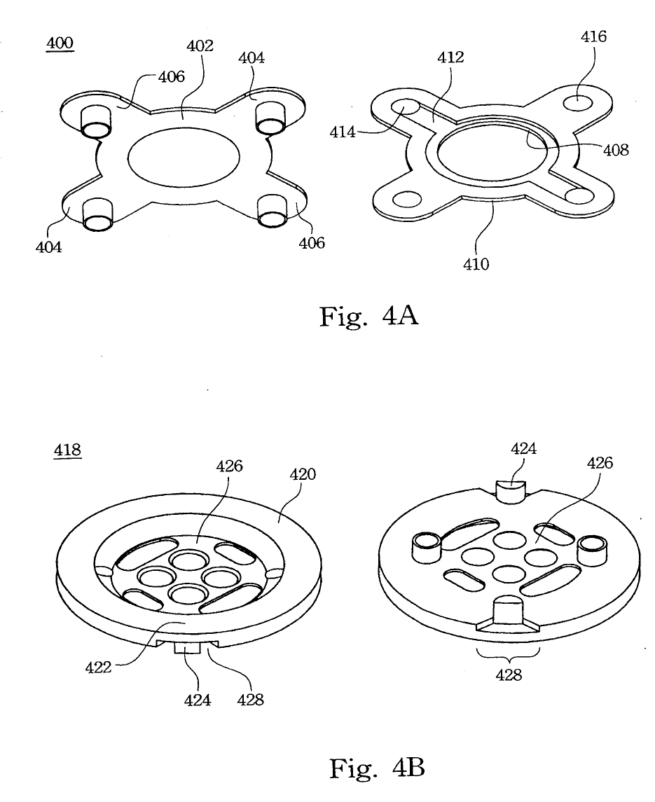

Please refer to FIG. 2, a general view of the substrate structure for LED chips operation with wire bonding chips thereon according to the first embodiment of the present invention. The LED chip 202 is wire bonded to the conductive plating 208 around the opening of the circuit layer 108 for connecting the LED chip 202 to a power source. The LED chip 202 is also connected in series with the LED chip 204 via wire bonding with the transfer pad 206. The use of transfer pads are necessary due to the limitation of direct wire bonding between LED chips. A LED chip pad may not be able to sustain the force applied by wire-to-pad engagement, therefore necessary for the use of transfer pad 206. The LED chip 204 is wire bonded in the similar configuration. The LED chips 202 and 204 will be lit by the current flowing from the power supplied at the access interface 208 to the plating 210 around the opening of the circuit layer 108, to the LED chip 202, to the transfer pad 206, to the conductive plating 214, and finally to the access interface 216. Each row of the LED chips is arranged the same.

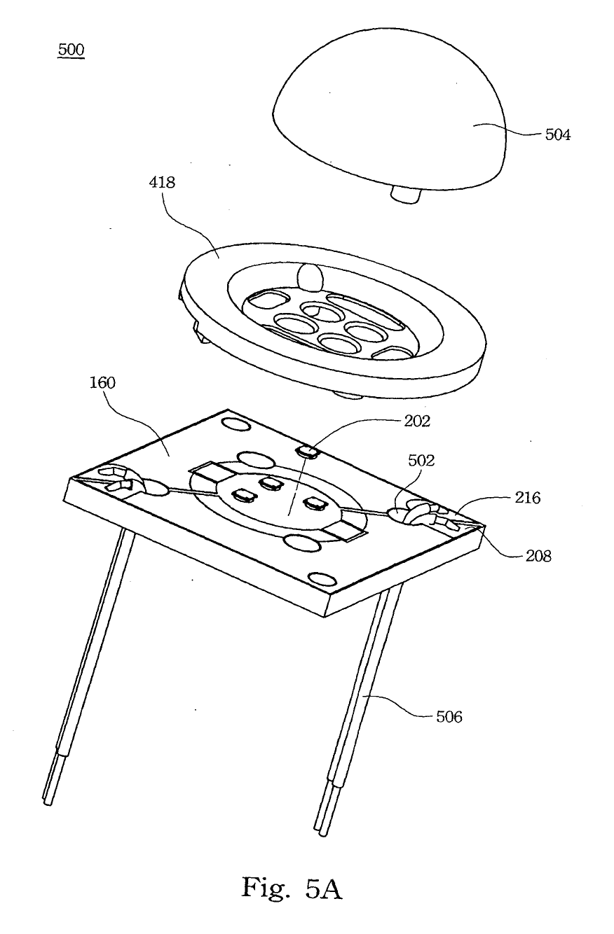

Please refer to FIG. 3, a top view of the substrate structure for LED chips operation with wire bonding chips thereon according to the first embodiment of the present invention. In this example, a 3×3 array of LED chips 302 are mounted onto the substrate structure. Each row of the array is connected in series via transfer pads 304. The transfer pads 304 are located between the LED chips 302 to simplify the wiring complexity. This wire bonding via transfer pads configuration may be applied to further expansions such as a 4×4, 5×5 array of LED chips and so on.

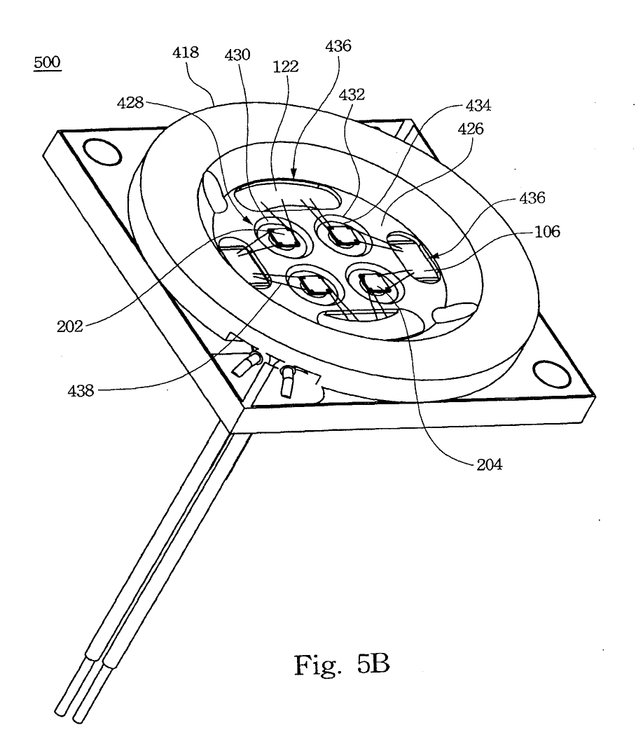

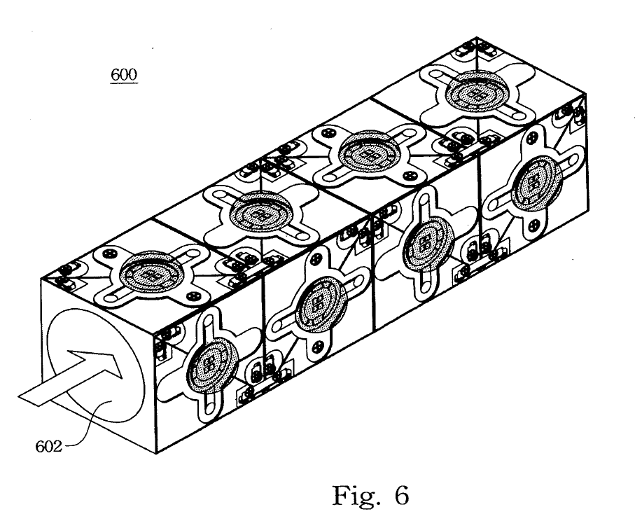

Please refer to FIG. 4A, a top and bottom view the spotlight cup according to a second embodiment of the present invention. The spotlight cup 400 includes a body frame 402, a pair of fastening portions 404, and a pair of filling portions 406. The body frame 402 having a ring shape with an inner surface 408 and an outer surface 410. The inner surface 408 is slanted outwardly for a wider focus angle. The slanted inner surface 408 may also be of a curved surface. Extending in opposite directions from the outer surface 410 of the body from 402 are the fastening portions 404 and the filling portions 406. The fastening portions 404 are for fixing the spotlight cup 400 onto the substrate structure. The fastening portions 404 have fastening holes 416 thereon for fasteners insertion. The filling portions 406 are for containing gel injected from the backside of the substrate structure and shaped by a mold 412 formed on the body frame 402 and the filling portion 406. Filling holes 414 on the filling portions provide the entrance for the gel to be injected from the backside of the substrate structure.

As a third embodiment of the present invention, please refer to FIG. 4B, a top and bottom view of an alternately spotlight cup 418. The filling portion 420 and the fastening portions 422 are defined as extending the overall circumference of the spotlight cup 418 rather than defining finger-like portions such as fastening portions 404 and filling portions 406. Instead of having fastening holes such as fastenings holes 416 on the fastening portion 422, a cable opening 428 is designed to allow electric cables to pass through for connection with the access interfaces 208 and 216. Also, a plug portion 424 is extended from the fastening portion 422 for plugging the spotlight cup 416 into the substrate structure 100. Furthermore, the spotlight cup 416 according to the third embodiment of the present invention is design to improve the brightness of the LED chips on the substrate structure 100. In other words, to maximize the visibility of light emitted from the LED chips. Therefore, a cover plate 426 is designed to cover the center of the substrate structure 100. How the cover plate 426 achieves this purpose is discussed more extensively in the later description of the LED circuit module.

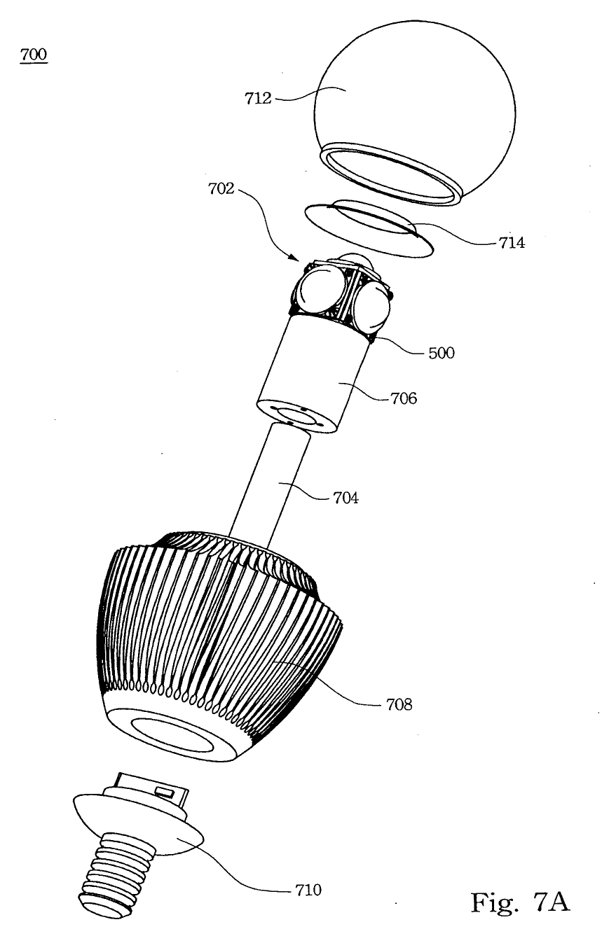

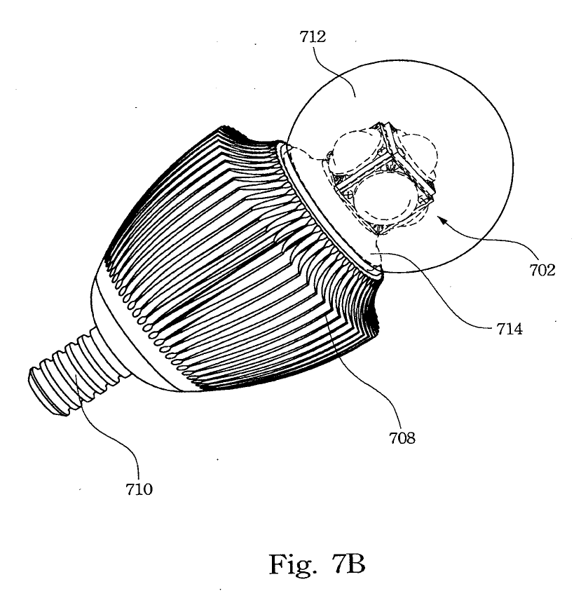

Please refer to FIG. 5A, an exploded view of a LED circuit package according to a fourth embodiment of the present invention. The LED circuit package 500 includes LED chips 202, a substrate structure 100, and a spotlight cup 418. The LED chips 202 are electrically connected to bond wires, respectively, for I/O access. In this embodiment, the LED chips 502 are arranged in a 2×2 arrangement, and may also be a 3×3 arrangement according to the first embodiment of the present invention. The spotlight cup 418 is fastened onto the substrate structure 100 via plug portions 424 plugging into the substrate holes 502. As mentioned above, gel is injected into the spotlight cup 416 from the backside of the substrate structure 100 and is contained by a gel cap 504. The gel cap 504 is designed to fit into the mold protecting the LED chips 202. In addition, electric cables 506 are inserted through the substrate holes 502 and connected to the access interfaces 208 and 216, respectively. The connection may be a solder connection. The other end of the electric cable 506 is connected to a power supply (not shown) to provide biasing voltages for lighting the LED chips 202.

Please refer to FIG. 5B, a general view of the LED circuit package 500 according to the fourth embodiment of the present invention. In FIG. 5B, notice the cover plate 426 has circular openings 428 located to encompass individual LED chips such as LED chips 202 and 204. Each circular opening 428 has a secondary slanted inner surface 430. The circular openings 428 are wider at the top towards an upper edge 432, and narrower at the bottom towards a lower edge 434. The purpose of the slanted inner surface 430 is to reflect the light emitted by each individual LED chips out of the spotlight cup 418. Without the cover plate 426, the light emitted by the LED chips will be partially absorbed by other LED chips decreasing the overall brightness of the LED circuit package 500. Therefore, each secondary slanted inner face 430 ensures light emitted by each LED chip such as LED chip 202 is emitting out of the spotlight cup 413 to its full brightness.

Furthermore, in order for the inner surface 430 to properly reflect the light emitted by the LED chips such as LED chip 202, the vertical position of the LED chip 202 is to be lower than the upper edge 432 and higher than the lower edge 434 so that the horizontally emitted light from the LED chip 202 is reflected off the secondary slanted inner surface 430. The vertical position of the LED chip 202 may be adjusted by the thickness of the conductive adhesive cushioning the LED chip 202.

Lastly, the bond wires connecting the LED chips such as LED chips 202 and 204 may be as configured in FIG. 2, or may be wired over the cover plate 426 after the spotlight cup 416 is assembled onto the substrate structure 100 as illustrated in FIG. 5B. Therefore, the cover plate 426 further includes pad openings 436 for exposing the transfer pads 106 and the plating 122. The bond wires 438 are connected to the LED chip 202 and 204 at one end, and the bond wires 438 cross over the cover plate 426 and have the other end connect to the transfer pads 106 and the plating 122. In this case, the spotlight cup 416 is made of a non-conductive material or is coated with such material in order to prevent the bond wires from conducting with the spotlight cup 416. Regardless of whether the bond wires are under or above the cover plate, they are isolated by the gel injected into the spotlight cup 416.

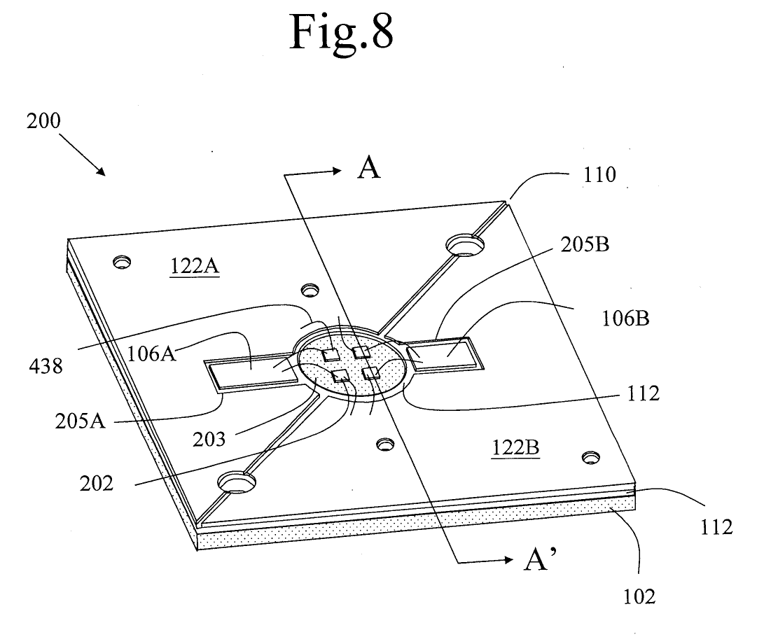

The connected packages may be applied to applications requiring stronger light emissions such as taillights and headlights of vehicles. Furthermore, referring to FIG. 6, a 3-dimensional (3D) assembly 600 of the LED circuit packages 500. The 3D assembly 600 may be used as lighting tubes such as lighting under water, wherein the hollow center of the 3D assembly may provide cooling channel 602 to the LED circuit packages 500. Water may flow through the cooling channel 602 to carry away the heat generated by the 3E assembly 600.

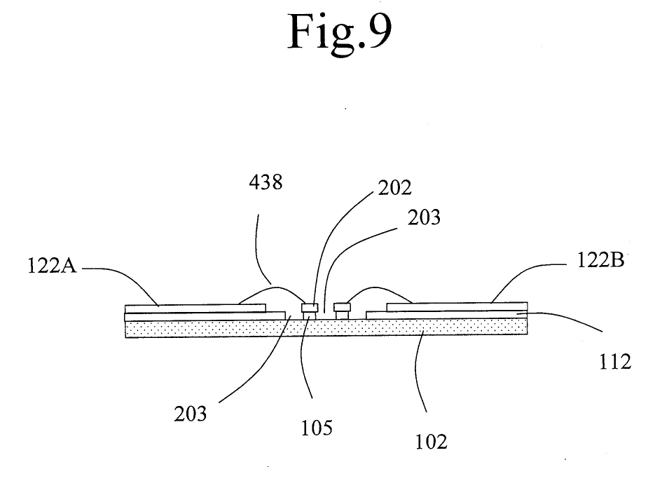

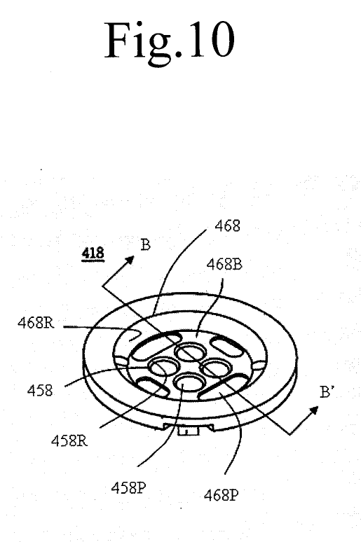

In another application of the LED circuit package 500, the LED circuit packages 500 may be assembled into a general purpose light bulb 700 as illustrated in FIG. 7A and FIG. 7B. FIG. 7A is an exploded view of the general purpose light bulb 700. FIG. 7B is an assembled view of the general purpose light bulb 700. The LED circuit packages 500 form a cubic lighting core 702 with five light emitting surfaces. The lighting core 702 engages with a heat pipe 704, which is inserted into a heat conducting shaft 706. The heat conducting shaft 706 is then inserted into a cooling structure 708. Therefore, the thermal energy generated by the lighting core 702 is transferred from the substrate structure 100, to the heat pipe 704, then from the heat pipe 704 to the heat conducting shaft 706, and finally the thermal energy is released through the cooling structure 708. The general purpose light bulb 700 further includes a light bulb connector 710 connected to the electric cables (not shown) of the LED circuit packages 500, a lighting shield 712 to cover the lighting core 702 and a shield support 714 for positioning the lighting shield 710.

From the embodiments of the present invention, a new LED substrate structure is disclosed, which provides multiple LED chips to be assembled onto a single substrate. A spotlight cup is also disclosed to reflect the light emitted by the LED chips so that to maximize the visible brightness of the LED chips. Lastly, by integrating the substrate structure and the spotlight cup together, a new LED circuit package is disclosed, which multiple LED circuit packages may be connected and configure to new products such as taillights, underwater lighting devices, and general purpose light bulbs. Therefore, the LED circuit packages according to the embodiments of the present invention provides a flexible structure where the packages may be used as a light source wherever applicable. Also, with multiple LED chips on a single substrate structure, the brightness of the LED circuit package is significantly brighter than what is allowed in the prior art.

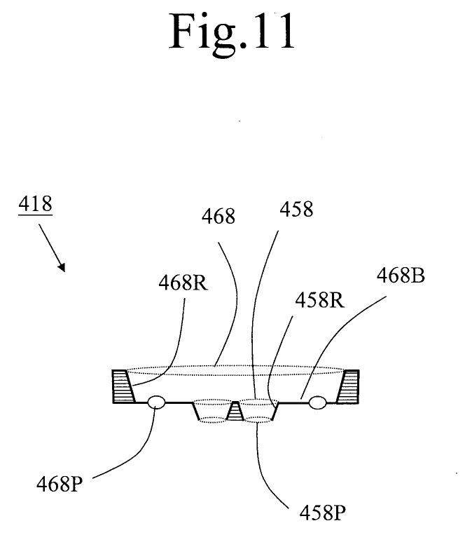

FIG. 8 is a three dimensional view for the LED package according to the present invention.

An alternative LED package 200 according to the present invention is shown in FIG. 8. A heat spreader 102 is configured on the bottom, an insulation layer 112 is applied on top surface of the heat spreader 102 but leaving a central clearance 203 to expose the heat spreader 102 so that at least an LED chip 202 can be mounted on the heat spreader 102. A first conductive plating 112A and a second conductive plating 122B is configured on top surface of the insulation layer 112. A gap 110 is formed between the first conductive plating 112A and the first conductive plating 112B diagonally so that the first conductive plating 122A is electrically independent from the second conductive plating 122B. The first conductive plating 122A further leaves a first clearance 205A near the central clearance 203. The second conductive plating 122B further leaves a second clearance 205B near the central clearance 203. A first transfer pad 106A is formed on the first clearance 205A and electrically independent from the second conductive plating 122B; a second transfer pad 106B is formed on the second clearance and electrically independent from the second conductive plating 122B. Bond wires 438 are for electrical connection between the LED chip(s) 202, the first conductive plating 122A, the second conductive plating 122B, and the first transfer pad 106A and the second transfer pad 106B. The LED chip 202 has a first top electrode electrically coupling to one of the transfer pads 106A, 106B and has a second top electrode electrically coupling to one the conductive plating 122A, 122B.

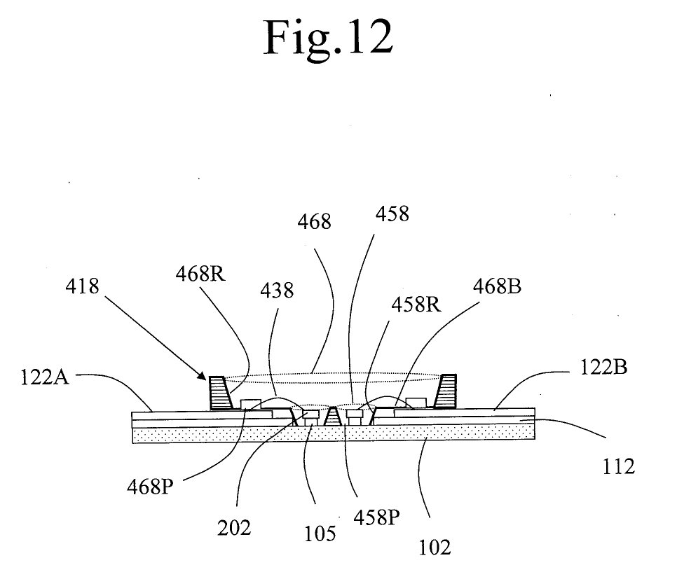

FIG. 9 is a section view along section line AA′ of FIG. 8.

An insulation layer 112 is applied on top surface of the heat spreader 102, a central clearance 203 is made in the middle to expose the heat spreader 102. A first conductive plating 122A is configured on top left of the insulation layer 112; and a second conductive plating 122B is configured on top right of the insulation layer 112. LED chips 202 are mounted on the hear spreader 102 in the central clearance 203. Solder slug 105 is configured under each of the LED chips 202 for bonding the each of LED chips 202 to the heat spreader 102.

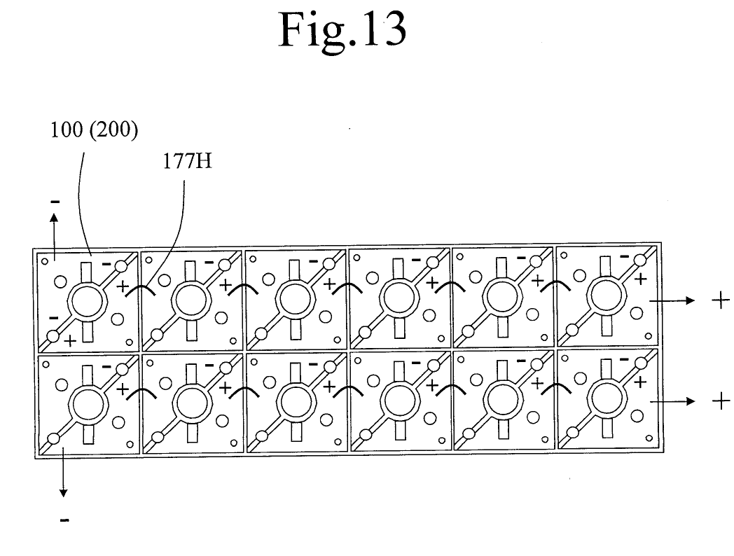

FIG. 10 is a step cup used in this invention.

A step cup 418 used in the present invention is as shown in FIG. 10, the step cup 418 is composed of an upper cup 468 and at least one lower cup 458. The upper cup 468 has an upper reflection wall 468R and a flat bottom plate 468B. The lower cup 458 is made below the flat bottom plate 468B. The lower cup 458 has a lower reflection surface 458R and has an open bottom 458P. There are at least one bonding open 468P is made on the flat bottom plate 468B for the bonding wire 438 to pass through. The bonding wire 438 electrically couples the top electrodes of the LED chip 202 either to one of the conductive plating 102A, 102B, or to one of the transfer pads 106A, 106B.

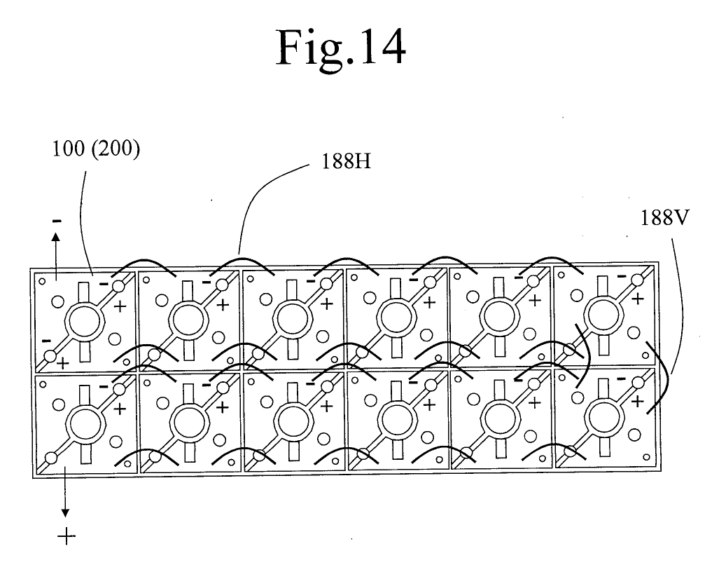

FIG. 11 is a section view along line BB′ of FIG. 10.

A section view along line BB′ of FIG. 10 shows a step cup 418 used in the present invention. The section view shows the step cup 418 includes an upper cup 468 and a lower cup 458. The upper cup 468 has a reflection wall 468R, and has a flat bottom plate 468B. The section view also shows two bonding opens 468P made through the flat bottom plate 468B. Two lower cups 458 are made below the flat bottom plate 468B, each of the lower cups 458 has an open bottom 458P.

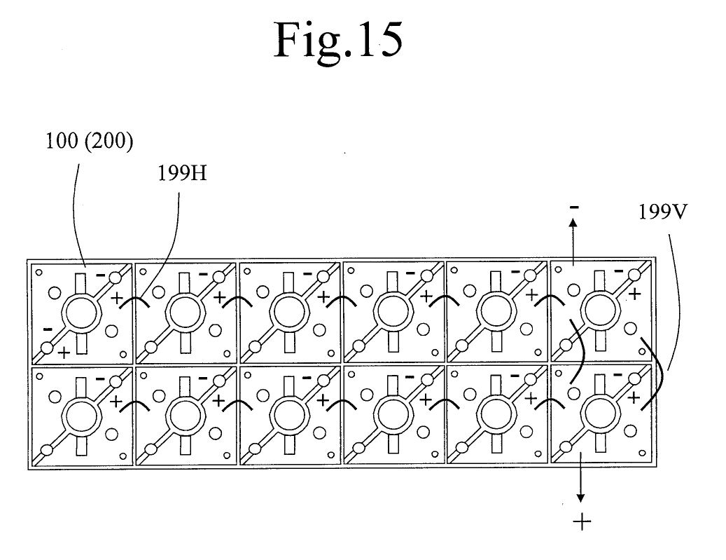

FIG. 12 is an assembly view of the step cup mounted onto the substrate stack.

FIG. 12 shows a step cup 418 mounted on a substrate stack. The lower cup 458 has a reflection wall 458R surrounding one of the LED chips. A left bond wire 438 electrically couples the left LED chip 202 to the first conductive plating 122A passing through a left bonding open 468P; a right bonding wire 438 electrically couples the right LED chip 202 to the second conductive plating 122B passing through a right bonding open 468P. Alternatively, the LED chip 202 is designed to have its top surface coplanar with the top surface of the conductive plating 122A, 122B so that the lower cup 458 has a reflection wall 458R extends under the bottom surface of the LED chip 202 to collect and reflect lateral light rays of the LED chip 202. The lower cup 458 in combination with the upper cup 468 reflects almost all the light rays emitted from the LED chip 202.

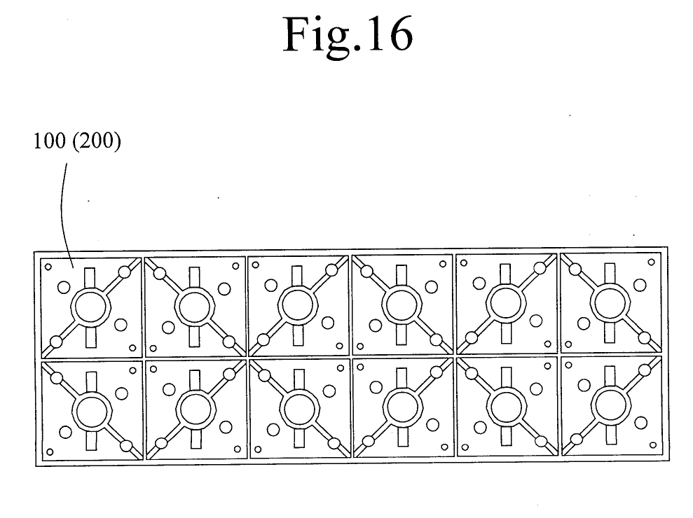

FIG. 13 is a substrate with 6*2 matrix pattern of the present invention.

FIG. 13 shows multiple units 100 (200) made on a same substrate stack with a common metal heat spreader 102 and a common insulation layer 112. Wires 177H, 177V connects opposite electrodes of horizontally neighboring units to form two strings of LED package units in serial connection.

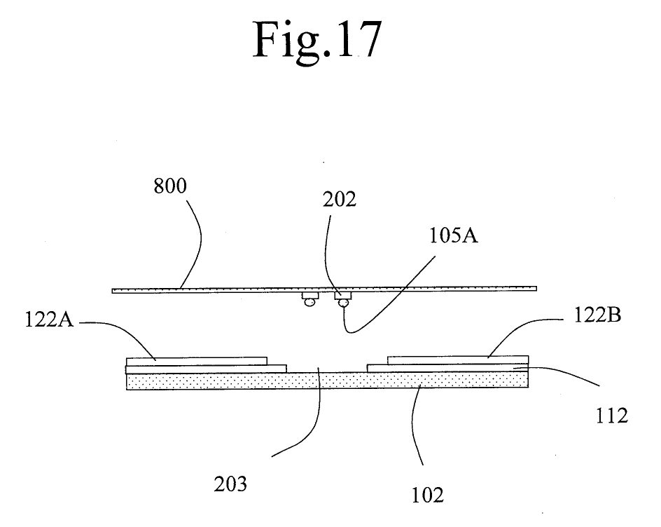

FIG. 14 is a parallel connection for the units on the substrate stack of FIG. 13.

FIG. 14 shows multiple LED package units 100 (200) made on a same substrate with a common metal heat spreader 102 and a common insulation layer 112. Wires 188H connects same electrodes between horizontally neighboring units to form two strings of LED units in serial connection. Wire 188V connects same electrodes between the two strings to form a parallel connection of the two serial connection strings.

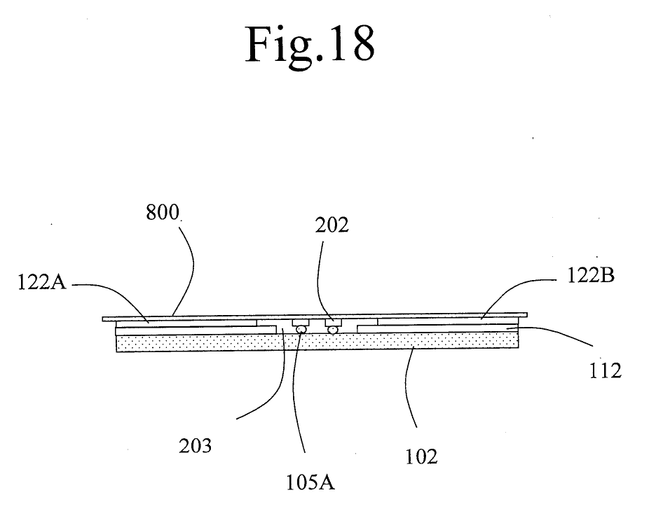

FIG. 15 is a serial-parallel connection for the units on the substrate stack of FIG. 13.

FIG. 15 shows multiple LED package units 100 (200) made on a same substrate with a common metal heat spreader 102 and a common insulation layer 112. Wires 199H connects opposite electrodes between horizontal neighboring units to form two strings of LED units in serial connection, and wires 199V connects same electrodes of the two strings to form parallel connection of the two serial connection strings.

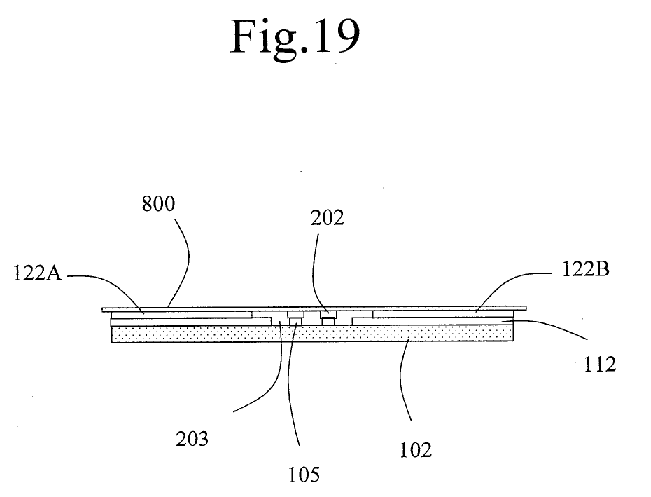

FIG. 16 is an alternative pattern for the units on the substrate stack.

FIG. 16 shows an alternative pattern of the LED package units formed on a same substrate.

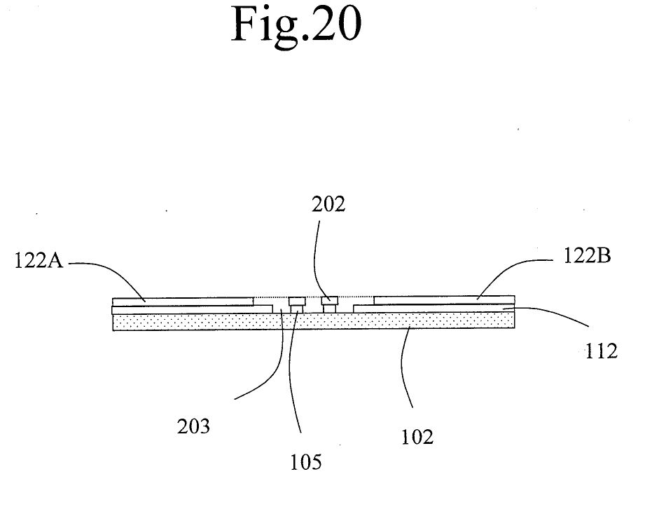

FIG. 17˜20 is a process for mounting the LED chip onto the substrate stack.

FIG. 17 shows two LED chips 202 are fixed on the bottom surface of the tape 800, and solder ball 105A is bonded to the bottom surface of each of the LED chips 202. A substrate stack is placed underside with a central clearance 203 aligned with the LED chips 202. FIG. 18 shows the tape 800 fixed onto the top surface of the conductive plating 122A, 122B with the LED chips 202 sitting in the central clearance 203. Referring to FIG. 19, the solder ball 105A is then heated to melt and solidify to be a solder slug 105 to fix the LED chip 202 onto the heat spreader 102 in the central clearance 203. Referring to FIG. 20, the LED chips 202 is fixed in position after removing the tape 800. The tape 800 makes the LED chips 202 having a top surface coplanar with the top surface of the conductive plating 122A, 122B.

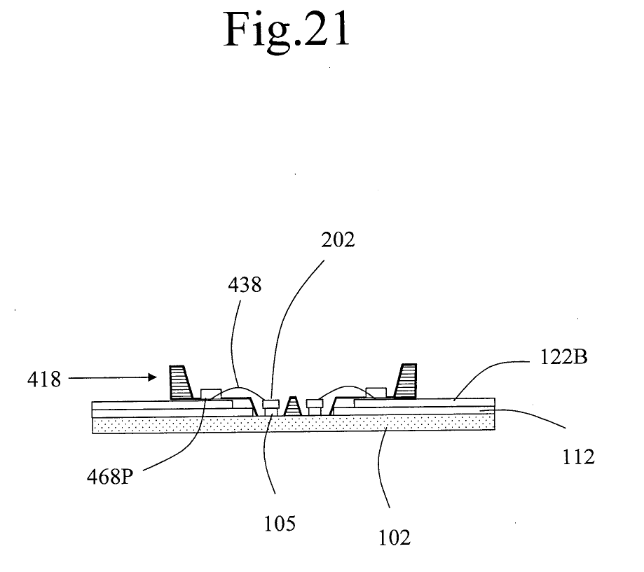

FIG. 21 is an assembly view for a step cup mounted on a substrate stack.

FIG. 21 shows a step cup 418 mounted onto a substrate stack and then wire 438 is used for electrically connecting the LED chip 202 to the conductive plating 122A, 122B passing through the bonding open 468P.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A substrate stack for mounting a light emitting diode, comprising:
a rectangular heat spreader;
an insulation layer, configured on top of the heat spreader; having a central clearance to expose the heat spreader;
a first conductive plating, configured on the insulation layer;
a second conductive plating, configure on the insulation layer electrically independent from the first conductive plating with a gap diagonally in between.

2. The substrate stack of claim 1, wherein the heat spreader is a copper plate.

3. The substrate stack of claim 1, wherein one of the first conductive plating and the second conductive plating is made of copper.

4. The substrate stack of claim 1, wherein one of the first conductive plating and the second conductive plating is made of gold.

5. The substrate stack of claim 1, wherein the first conductive plating comprising a first clearance; and
a first transfer pad is configured on the insulation layer in the first clearance and electrically independent from the first conductive plating.

6. The substrate stack of claim 5, wherein the second conductive plating comprising a second clearance; and
a second transfer pad is configured on the insulation layer in the second clearance and electrically independent from the second conductive plating.

7. A light emitting diode package, comprising:
a plurality of LED chips, mounted on the heat spreader in the central clearance of claim 1.

8. The light emitting diode package of claim 7, wherein the LED chip has a first top electrode electrically coupling to one of the transfer pads, and has a second top electrode electrically coupling to one of the conductive platings.

9. The light emitting diode package of claim 7, wherein the LED chip has a top surface coplanar with a top surface of the first conductive plating.

10. The light emitting diode package of claim 7, further comprising:
a step cup, comprising:
an upper cup, having a flat bottom plate; and
a lower cup, below the flat bottom plate; wherein the lower cup has a reflection wall surrounding the LED chip; wherein the lower cup has an open bottom.

11. The light emitting diode package of claim 10, wherein said step cup further comprising an open for passing through a bonding wire.
